(19) United States
(12) Patent Application Publication
(10) Pub. No.: US 2008/0173877 A1
(43) Pub. Date: Jul. 24, 2008

(54) SEMICONDUCTOR APPARATUS

(75) Inventor: Sataro YAMAGUCHI, Aichi (JP)

Correspondence Address: SUGHRUE MION, PLLC, 2100 PENNSYLVANIA AVENUE, N.W., SUITE 800, WASHINGTON, DC, 20037, US

(73) Assignee: KABUSHIKI KAISHA Y.Y.L., Tokyo (JP)

(21) Appl. No.: 11/970,561

(22) Filed: Jan. 8, 2008

(30) Foreign Application Priority Data
Jan. 9, 2007 (JP) 2007-001556
Dec. 27, 2007 (JP) 2007-337579

(51) Int. Cl. H01L 31/12

(52) U.S. Cl. 257/80; 257/E21.703

(57) ABSTRACT

Disclosed is a semiconductor apparatus having a channel region of a substrate irradiated with light via a transparent gate electrode and a transparent gate insulating film to decrease channel resistance.

### REFERENCE TO RELATED APPLICATION

This application is based upon and claims the benefit of the priority of Japanese patent applications No. 2007-1556, filed on Jan. 9, 2007 and No. 2007-337579, filed on Dec. 27, 2007, the disclosure of which is incorporated herein in its entirety by reference thereto.

### FIELD OF THE INVENTION

This invention relates to a semiconductor apparatus and, more particularly, to a structure that may be applied with advantage to a power-MOSFET or an IGBT.

### BACKGROUND OF THE INVENTION

In a MOSFET (lateral MOSFET), a gate electrode is provided, with the interposition of a gate oxide film, between source and drain diffusion layers (n+ regions) on the surface of a p-type substrate, for instance. If a preset gate voltage is applied, electrons in the substrate are attracted, under the Coulomb's force, towards the gate electrode, to form a channel region through which flows the current. The on-resistance is determined by the gate voltage (gate-to-source voltage). The MOSFET is on/off controlled by exploiting an electrostatic field. Among known devices, exploiting the electrostatic field, there are a JFET (Junction gate Field Effect Transistor), a MESFET (Metal Semiconductor Field Effect Transistor) and an IGBT (Insulated Gate Bipolar Transistor).

In a power MOSFET (vertical MOSFET), a drain terminal is provided on a bottom surface of an n-substrate, for instance, and source and gate terminals, connected to n+ regions in p-regions of an n− epitaxial layer, are mounted on an upper side of the substrate. A gate electrode is provided on the top of the n− epitaxial layer via an insulating layer. On application to the gate electrode of a positive voltage, electrons are attracted towards the substrate, and hence the n− epitaxial layer and the source are rendered electrically conductive, via the p-region, so that the electrons are moved to the drain. The on-resistance is lowered by using a small-sized gate and by arranging the gate on the entire upper surface of the substrate. In a vertical MOSFET, a larger current may be caused to flow than in a lateral MOSFET. However, if the large current is to flow in the vertical MOSFET, the substrate is large-sized. In this case, since the gate capacity is increased, switching at a higher frequency becomes difficult.

In an IGBT (Insulated Gate Bipolar Transistor), used for controlling the larger power, the collector is on the bottom surface of a p-type substrate, and the emitter is taken out from an emitter electrode, connected to a diffusion region of an epitaxial layer. The gate of the IGBT is taken out from a gate electrode provided on top of the epitaxial layer via an insulating film. The IGBT differs from the vertical MOSFET in that it has a p-region provided on the bottom side.

This increases the carrier density and lowers the on-resistance to make the IGBT suited for high-power applications. The IGBT is uni-polar, insofar as switching control is concerned, and hence it is possible to reduce power consumption. It is bi-polar insofar as the on-resistance is concerned. The turn-off time is longer than with the MOSFET, with the switching time being longer.

FIG. 10, cited from the drawing of the Non-Patent Document 1, shows the structure of the IGBT and the carrier flow in the course of the on-operation. From the collector side, holes flow upwards, whereas, from the emitter side, electrons flow downwards. Thus, carrier recombination takes place in a mid region. Moreover, a parasitic npn transistor is formed, as shown, so that, if the high current flows, the electrically conductive state may be maintained, thus possibly leading to loss of the turn-off function. In addition, the current path is relatively long. Hence, a trench IGBT (TIGBT) has been developed to reduce the on-resistance.

FIG. 11, cited from the MITSUBISHI DENKI HP, depicts a perspective view showing an example of a trench IGBT. The gate electrode is of the vertical type and extended into an n-region. This reduces the current path length and the on-resistance. An example of known IGBTs is a CSTBT (Carrier Stored Trench gate Bipolar Transistor). The CSTBT differs from TIGBT in that it has a carrier stored n layer. The trench electrode structure has been used in a lateral MOSFET, for instance. In a DRAM, the trench electrode structure has been used as from an earlier time than in the IGBT or the power MOSFET, and represents customary means for reducing the resistance. Although FIG. 5 shows a single unit, a plural number of units are ordinarily used on one and the same chip.

FIG. 12, cited from the drawing of the Non-Patent Document 1, illustrates the on-resistance of the power MOSFET. A source resistance Rs and a drain resistance Rd are determined by the voltages of the source electrode and the drain electrode, respectively, and are of relatively low values. The on-resistance of the device is determined by Rch (channel resistance) and Repi. The channel resistance Rch is a resistance the current meets when flowing through electrical charges attracted by the gate, and is of a high resistance value because of the thin current path of the channel. Repi is a resistance when the current flows through the epitaxial layer. In the IGBT, for example, the resistance Repi is low because of the high carrier density.

FIG. 13, cited from the drawing of the Non-Patent Document 1, depicts a graph showing the general relationship between the collector-to-emitter voltage (VCE) of the IGBT or the bipolar junction transistor (BJT) or the drain-to-source voltage of the MOSFET on one hand and the output current on the other hand. With the bipolar device, the current increases abruptly with rise in voltage, and is finally saturated. On the other hand, with the MOSFET, the current is monotonously increased with rise in the voltage.

[Non-Patent Document 1] Hiroshi YAMAZAKI, ‘Introduction to Power MOSFET/IGBT’, published by NIKKAN KOGYO SHIMBUN-SHA, July 2002

### [Non-Patent Document 2] IEEE Photonics Technology Letters, Vol. 16, No. 1, p 117, 2004

### SUMMARY OF THE DISCLOSURE

The following analysis is given by the present invention. The disclosure of the above-mentioned Non-Patent Documents 1 and 2 is herein incorporated by reference thereto.

It is an object of the present invention to provide a semiconductor apparatus that decreases channel resistance of a power device, such as a power MOSFET or an IGBT.

According to the present invention, there is provided a semiconductor apparatus including a light source for irradiating light to a channel region through which carriers move. The light source is turned on to allow the flow of a channel current.

According to the present invention, a light source for irradiating light to a gate portion is provided within the semiconductor apparatus.

The light source is adapted to be on/off controlled.

The semiconductor apparatus according to the present invention may include a lateral MOSFET.

The semiconductor apparatus according to the present invention may include a vertical MOSFET.

The semiconductor apparatus according to the present invention may include an IGBT (Insulated Gate Bipolar Transistor). A light reflective plate may be provided at the bottom of a trench of a trench gate electrode of the IGBT.

According to the present invention, the gate electrode and the gate oxide film are composed of electrically conductive members transmissive to the light.

According to the present invention, an insulating resin transmissive to the light may be filled in between the gate electrode and the light source.

According to the present invention, the light source may be provided in a space between the side of the source electrode of the vertical MOSFET facing the gate electrode thereof and the gate electrode.

According to the present invention, the source electrode of the vertical MOSFET may include an opening having one end facing its gate electrode, and the light source is provided at the opposite end of the opening.

According to the present invention, an insulating resin transmissive to the aforementioned light may be filled in between the gate electrode and the light source.

According to the present invention, an emitter electrode of the aforementioned IGBT is provided with an opening having one end facing its gate electrode and having the other end facing the light source. A light reflective plate is provided on an end of the light source opposite to the other end of the opening.

The semiconductor apparatus according to the present invention may further comprise a light waveguide for guiding the light from the light source.

According to the present invention, a planar light emitting device as the light source may be provided facing a surface of the semiconductor apparatus provided with the gate electrode.

According to the present invention, the light source may be provided facing a surface of the semiconductor apparatus provided with the gate electrode. A light diffusing layer may be provided between the light source and the semiconductor apparatus, and a light emitting device having a light reflective plate is provided on a side of the light source opposite to the side thereof facing the light diffusing layer.

According to the present invention, the insulating resin that covers the gate electrode may be transmissive to the light from the light source.

According to the present invention, the light source may include an LED (Light Emitting Diode).

According to the present invention, a light shielding film member may be provided at a light interrupting site on a junction surface between the semiconductor apparatus and the light emitting device.

In the present invention, said light source may include a semiconductor laser.

In the present invention, said semiconductor laser may be composed of a silicon semiconductor laser.

In the present invention, said light source may include a silicon semiconductor laser formed on the same silicon wafer on which said switching element is formed.

In the present invention, said light source may include a silicon semiconductor laser formed on a same silicon wafer on which said switching element is formed.

In the present invention, said silicon semiconductor laser may be arranged next to a gate portion of said switching element and the light emitted from said silicon semiconductor laser is guided to illuminate the gate portion of said switching element from above thereof.

In the present invention, there is provided a mirror for reflecting said light from said silicon semiconductor laser so as to cause the reflected light to illuminate the gate portion of said switching element from above thereof.

The meritorious effects of the present invention are summarized as follows.

According to the present invention, on-resistance may be decreased because the channel current is controlled by application of a gate voltage and by light irradiation.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIGS. 1A and 1B schematically show an example of the present invention.

FIG. 2 is a schematic cross-sectional side view showing a first example of the present invention.

FIG. 3 is a schematic cross-sectional side view showing a second example of the present invention.

FIG. 4 is an exploded perspective view schematically showing a known semiconductor apparatus.

FIG. 5 is a schematic cross-sectional side view showing a third example of the present invention.

FIG. 6 is a schematic cross-sectional side view showing a fourth example of the present invention.

FIGS. 7A and 7B are photos showing a micro-light waveguide, FIG. 7C is a photo showing an optical computer and FIG. 7D is a photo showing a socket; the micro-light waveguide, socket and the optical computer being usable in association with a planar light emitting device of a fifth example of the present invention.

FIG. 8 is a schematic cross-sectional side view showing a sixth example of the present invention.

FIG. 9 is a schematic cross-sectional side view showing a seventh example of the present invention.

FIG. 10, a citation from the Non-Patent Document 1, schematically shows the carrier flow in the course of the IGBT operation.

FIG. 11, a citation from the HP of MITSUBISHI DENKI KK, is a perspective view showing a trench IGBT.

FIG. 12, a citation from the Non-Patent Document 1, schematically shows the on-resistance of a power MOSFET.

FIG. 13, a citation from the Non-Patent Document 1, is a graph showing voltage-current characteristics of the on-resistance of the power MOSFET.

### PREFERRED MODES OF THE INVENTION

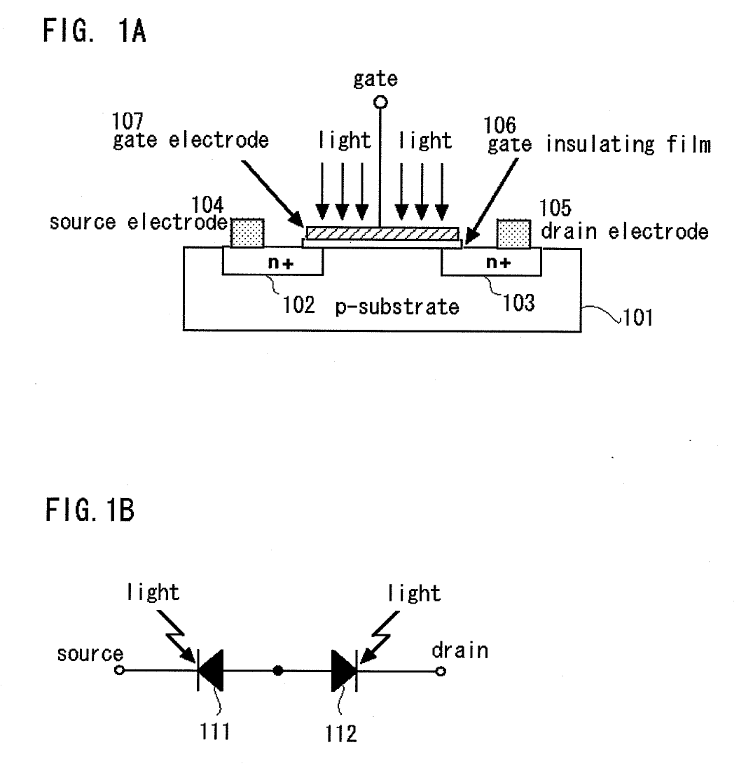

The present invention will be described in detail with reference to the accompanying drawings. FIG. 1A illustrates the principle of a MOSFET according to one mode of the present invention. Referring to FIG. 1A, an n+ region (source diffusion region) 102 and another n+ region (drain diffusion region) 103 are formed on a surface of a p-substrate 101, and are provided with electrodes 104 and 105, respectively. These electrodes 104 and 105, which serves as source and drain electrodes, respectively, are formed from aluminum or copper in accordance with a known semiconductor fabrication process. A gate electrode 107 (transparent electrode) is formed on the p-substrate 101 via a gate insulating film 106. In case the p-substrate 101 is formed of silicon or SiC, the gate insulating film 106 is formed of silicon dioxide (SiO₂). The gate insulating film is of a film thickness of 1 μm, only by way of example. In a well-known manner, silicon dioxide (SiO₂) is optically transparent and transmissive to light ranging from infrared light to visible light and to ultraviolet light.

The gate electrode 107 is formed of an optically transparent electrically conductive material, such as ITO (indium tin oxide) or zinc oxide (ZnO). The gate electrode may also be formed of an optically transparent organic material.

In the present example, not only the gate voltage is applied to the transparent gate electrode 107, but also light is irradiated from the backside of the gate electrode, in order to cause the current to flow between the source and the drain. Since the voltage is applied to the gate electrode 107, electrons, as carriers, are attracted, as in a MOSFET, to form a channel region between the source 102 and the drain 103 to allow the current to flow therebetween. FIG. 1B depicts an equivalent circuit to FIG. 1A. In case, light is irradiated from the backside of the gate electrode, the current path between the source and the drain is turned on, even though one of the diodes is reverse-biased, in accordance with the same operating principle as that for a light emitting diode. By proper selection of the light wavelength, light may incident on the substrate 101. The region through which the channel current flows is enlarged to decrease the on-resistance. This device structure is here termed an optical MOSFET. The gate structure which may reduce the channel resistance by light irradiation is sometimes referred to as an optical gate. Although no limitation is imposed on the present invention, an LED (Light Emitting Diode) is used as a light source in the present example.

In a MOSFET, a semiconductor substrate is packaged so as to shield light, because light irradiation results in increased leakage current (the source-to-drain current flowing when a gate voltage less than a threshold voltage, for instance).

Conversely, the present example exploits light to control the on/off of the MOSFET to decrease the on-resistance. In case the gate voltage is applied to electro-statically attract electrons to form a channel, the thickness of the channel region is on the order of 1 μm (micrometer).

If, in the present mode of the invention, the MOSFET is to be turned on by light absorption, it is necessary for the energy of the irradiating light to be higher than the band gap energy. Although the depth reached by light depends on absorption coefficient, current conduction between source and drain may be assured by having the light reach the channel region. The depth to which the light can penetrate in the silicon substrate, is on the order of tens of μm to 100 μm, in case the light used is the visible light. The light irradiated may reach the channel region in the substrate surface region.

It is possible with the present mode of the invention to reduce the channel resistance as compared with the case of using only electro-static means, that is, only applying the gate voltage.

It is moreover possible with the present mode of the invention to arrive at the meritorious effect comparable to that obtained with the use of a trench electrode, even though the trench electrode is not used. That is, the on-resistance may be decreased to permit the large current to flow even though no trench is formed in the semiconductor substrate.

In order for a device on/off controlled by a gate voltage to switch at a high frequency, its gate capacity is reduced by reducing the gate in size or splitting of the gate. In the present mode of the invention, the LED of the light source emits light by application a voltage on the order of 2V. If a plurality of LEDs are connected in parallel to generate irradiating light, a transistor may be turned on with a lower gate voltage. The power consumption of the entire device may be reduced even if the power consumed by the LED is taken into account. The switching frequency of the small-sized LED is on the order of GHz, such that, in case the present invention is applied to an IGBT or a MOSFET, the switching frequency becomes higher than with the conventionally used device.

In the present mode of the invention, the light from a light source (LED) is used for on/off control of a transistor to improve its switching frequency. This is one of the features of the present invention.

### FIRST EXAMPLE

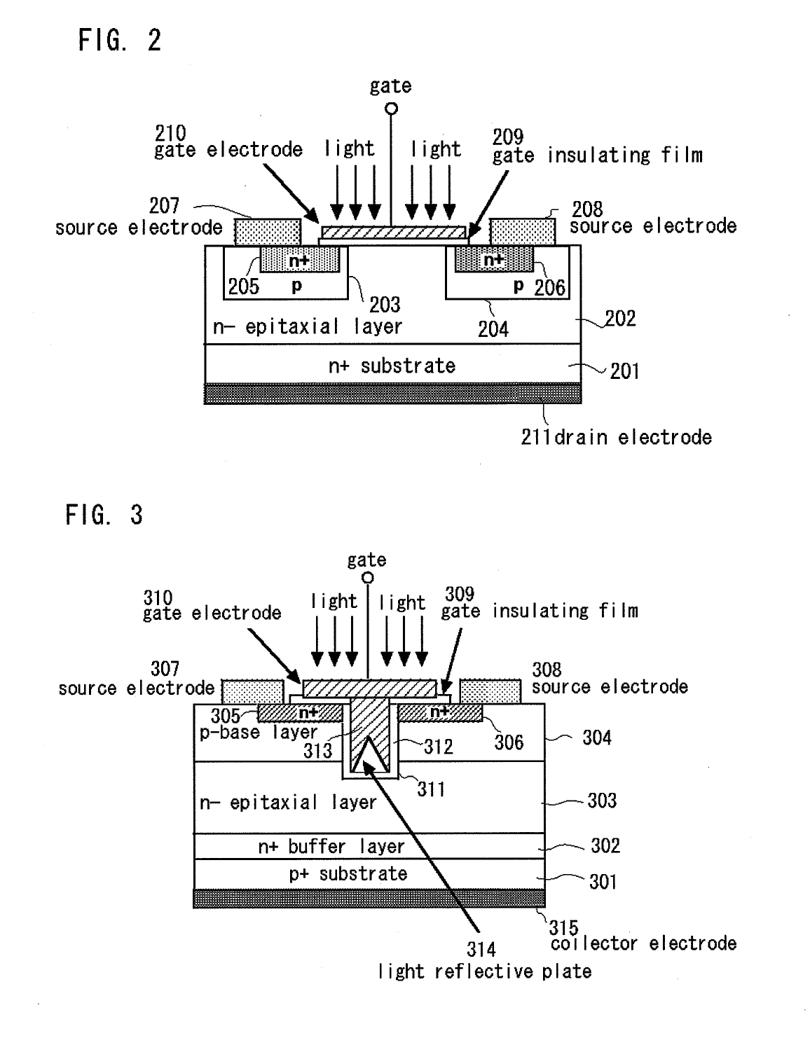

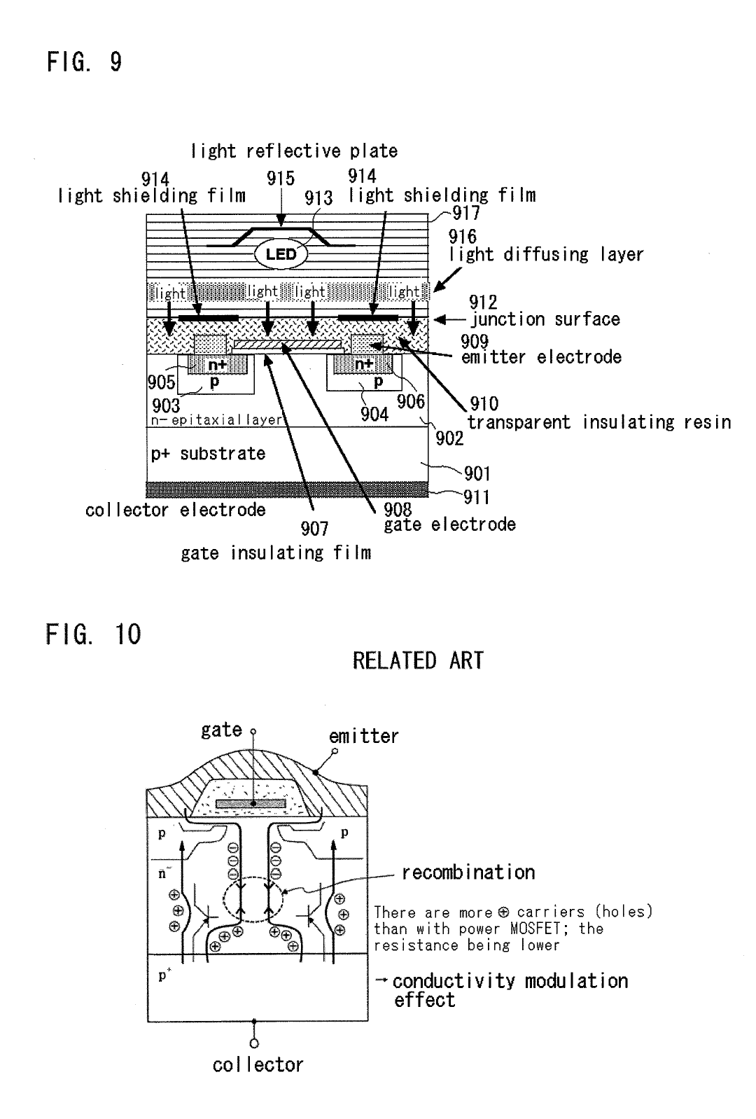

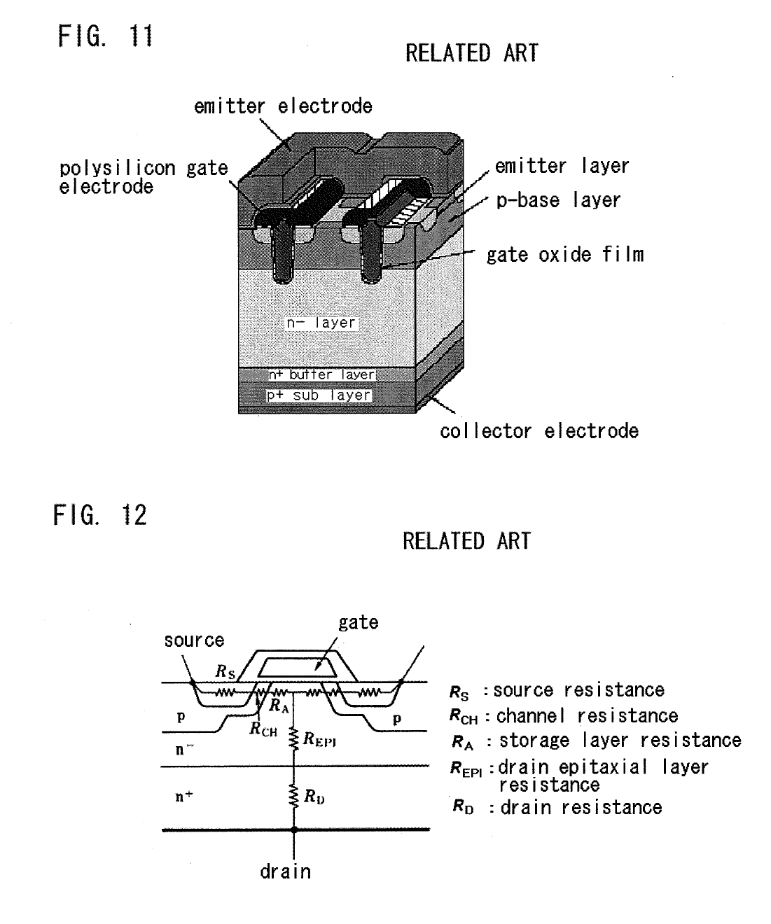

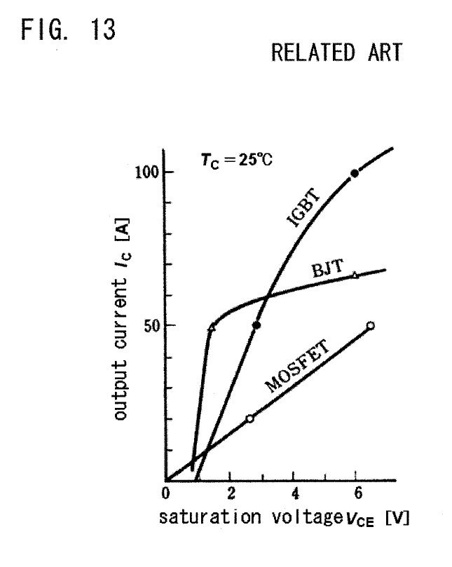

FIG. 2 shows the configuration of a first example of the present invention. In FIG. 2, there is shown a vertical MOSFET having an ‘optical gate’ structure in which light is irradiated from above the device. A gate insulating film 209 is an insulating film of a transparent material, and a gate electrode 210 is an electrically conductive film of a transparent material transmissive to irradiating light. The current flows from n+ regions 205 and 206, constituting source and drain diffusion layers, through p-layers (p-type wells) 203 and 204 and through an n− epitaxial layer 202. The current path is secured responsive to light absorption. Since light is introduced into the n− epitaxial layer 202, the resistance of the n− epitaxial layer 202 may be reduced, which is an instance of the light conduction effect. Although FIG. 9 shows the configuration of the vertical MOSFET, the present invention may be applied to the IGBT as well.

With the use of light, the electron density in the n+ layer 205, kept in contact with a source electrode 207, may be set to a lower value. This improves the insulation withstand characteristic, for instance. Although there is no particular limitation imposed on the present invention, the gate electrode (transparent electrode) 210 may be formed to a dimension of the order of several μm.

### SECOND EXAMPLE

FIG. 3 shows a second example in which the present invention is applied to a trench IGBT. The trench IGBT shown has an ‘optical gate’ structure, in which light is irradiated from above. A gate insulating film 309 and a gate electrode 310 are transmissive to the irradiating light. The current flows from n+ regions 305 and 306 through a p-base layer 304, an n− epitaxial layer 303, an n+ buffer layer 302 and through a p+ substrate 301 to secure a current path. The irradiating light is also introduced into the n− epitaxial layer 303, so that its resistance may be reduced. If plural light beams having different wavelengths are used, the light beams are absorbed after travelling variable distances, before the light beams are absorbed in the material that makes up the device. Hence, the channel current may be controlled accordingly. The light sources of LEDs with variable wavelengths may also be used.

A trench 311 is formed, right below the gate, between the n+ regions 305 and 306 that form a source diffusion layer and a drain diffusion layer, respectively. The trench has its inner wall covered up with an insulating film 312. A conically shaped light reflective plate 314 is provided at the bottom of the trench, with the pointed end of the cone pointing upwards. An electrically conductive member 313 is embedded above the light reflective plate 314 in the trench 311. The upper end of the electrically conductive member 313 is in contact with the bottom surface of the gate electrode 310 to make up a trenched gate electrode. The light reflective plate 314 in the trench renders it easy to form a channel region extending along the trench-shaped gate electrode.

### Comparative Example

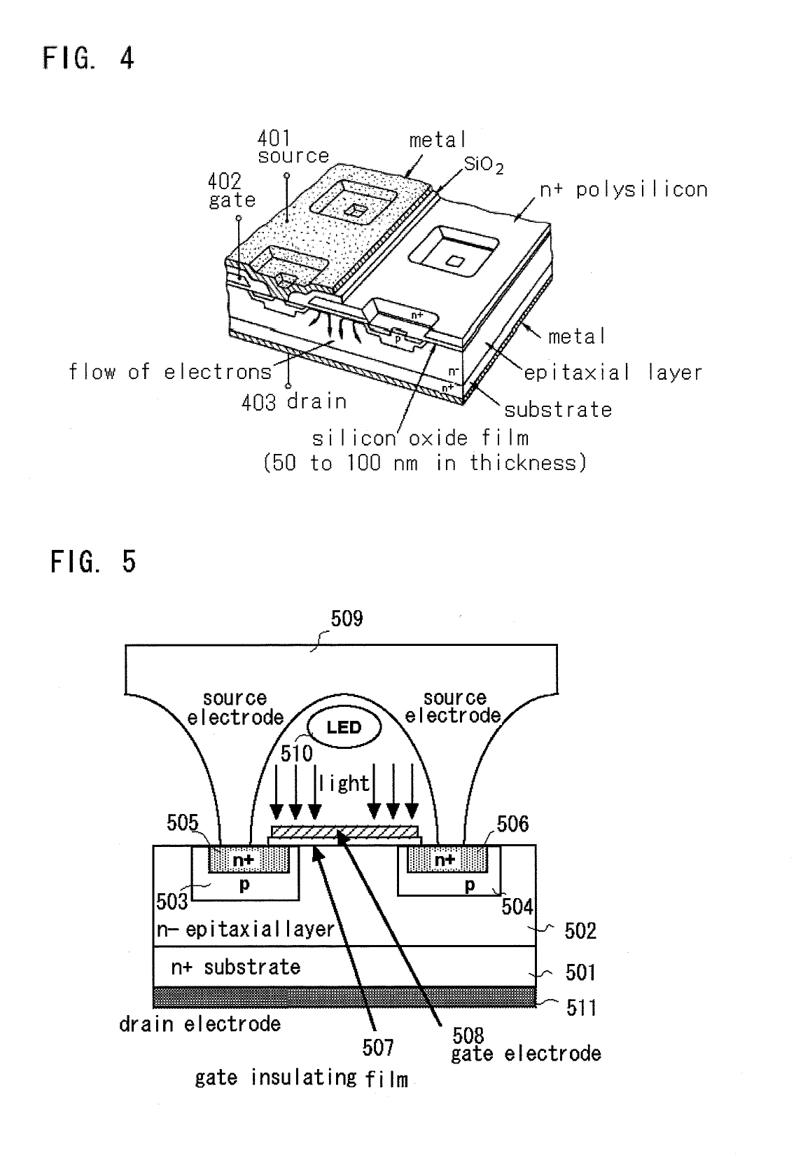

FIG. 4, cited from the Non-Patent Document 1, shows exemplary source side and gate side electrodes of a conventional MOSFET (vertical MOSFET). Since high current flows through a source 401, the electrode is mounted on substantially the entire major surface to reduce the resistance. Moreover, the heat generated is diminished by heat radiation. Since the current flowing through the gate is not that high, the gate electrode is connected at the end to serve as the device gate.

A third example of the present invention, as applied to a device of the configuration shown in FIG. 4, is now described. There are two techniques for mounting a light source (LED) in position and irradiating the light from it to the gate.

In the case of a MOSFET, an LED is mounted on an inner side of a source electrode (an emitter electrode in the case of the IGBT). The size of the light emitting part of the LED is on the order of 0.1 mm square.

### THIRD EXAMPLE

FIG. 5 shows the configuration of the third example of the present invention. An LED 510 is arranged on the inner side of a source electrode 509 connected to source diffusion layers (n+ regions 505, 506). An insulating layer (interlayer insulating film), not shown, is provided in a space between the source electrode 509 and the substrate surface and a space between the source electrode and the gate electrode 507. The LED 510 is smaller in size than the gate electrode 507, which gate electrode is extended in a direction perpendicular to the drawing sheet.

The LED 510 is wired so that its one end is connected to the gate electrode 507 and its other end is connected to the source electrode 509. In case the gate voltage is set to 10V for example, a high voltage is applied to the LED. Hence, the LED may be connected in series with the gate and source electrodes.

Since the source electrode 509 (emitter electrode in the case of the IGBT) is a metallic member, its inner illuminated side may be plated with aluminum or silver. A transparent resin (plastics) is filled in into a space between the LED 510 and the gate electrode 507 to serve as an interlayer insulating film.

Instead of mounting the LED 510 for each gate electrode 507 of an extremely small size, it is possible to provide in the source electrode 509 an opening through which to irradiate the light on the gate. Alternatively, the opening may be filled with a transparent electrode material.

### FOURTH EXAMPLE

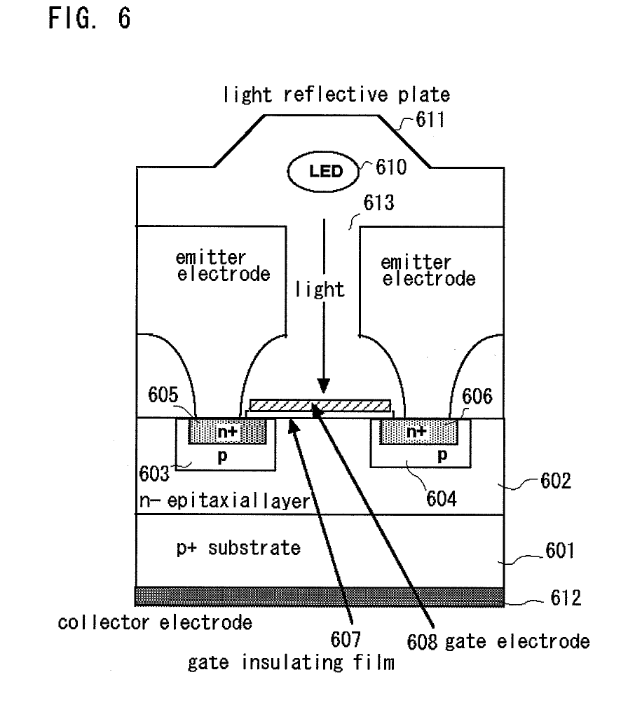

FIG. 6 shows the configuration of a fourth example of the present invention. There is shown an illustrative application of the present invention to an IGBT. An LED 610 is mounted on top of an emitter electrode 609. An opening 613 is bored in the emitter electrode 609 to conduct light to a channel forming region directly below the gate electrode. The emitter electrode 609 may be cut to form a groove along the direction in which the gate electrode 608 is arrayed. In this case, light diffraction is scarcely produced with the gate size in the order of several to about ten μm.

A light reflective plate 611 is provided facing the upper surface of the emitter electrode 609, with the LED 610 in-between. The light reflective plate 611 may be coated or plated with a reflective plate. The region of the emitter electrode 609, illuminated by light from the LED light source, may be coated or plated with a reflective material.

The inside of the opening 613, passed through by light from the LED 610, is filled in with an insulating transparent resin, not shown. A plural number of LEDs may be mounted in the present example. The light wavelengths may be selected taking transmission of light through a semiconductor substrate into account.

From the perspective of radiating light the IGBT or the MOSFET in its entirety with the LED, a light diffusing plate may be arranged between the LED and the emitter electrode in order to guide the light, emitted by the LED and diffused, to the channel forming region directly below the gate electrode.

### <Reference Example of Light Waveguide>

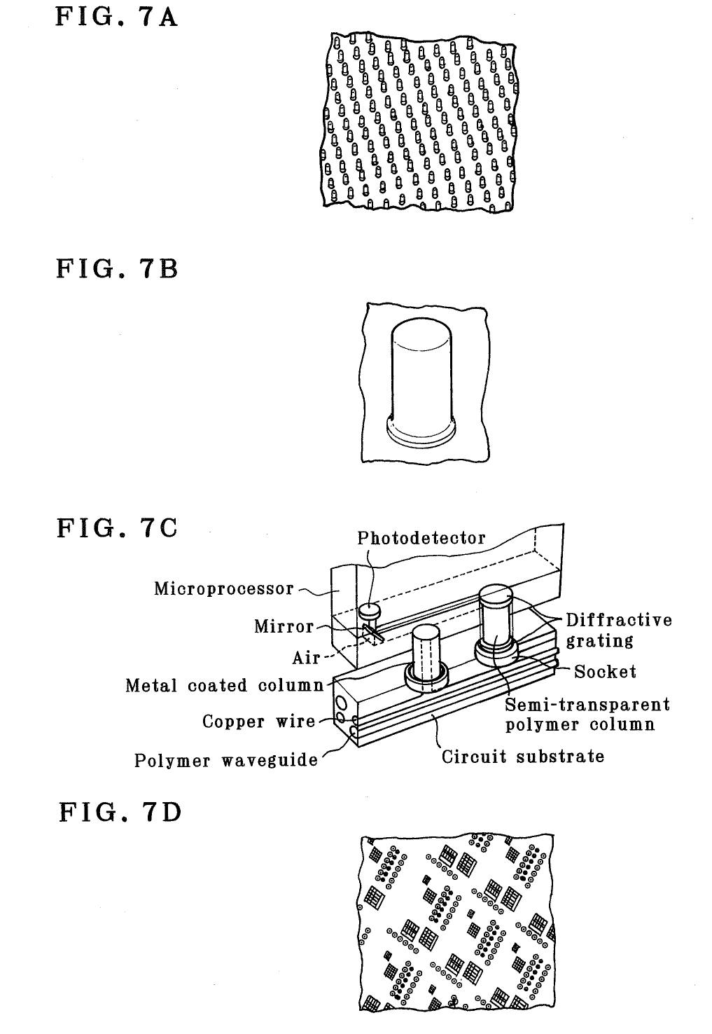

The drawing of FIGS. 7A to D, each of which is citation from the Non-Patent Document 2 (IEEE Photonics Technology Letters, Vol. 16, No. 1, p 117, 2004). It is noted that the present inventor has had nothing to do with the researches published in the Non-Patent Document 2 and which are shown herein in FIGS. 7A to D. The drawing of FIGS. 7A to D has been re-inserted in the present specification to assist in the understanding of the concept of the light waveguide. Thus, FIGS. 7A and 7B show a micro-light waveguide, FIG. 7 ( shows its socket and FIG. 7C shows an optical computer. FIG. 7A shows a waveguide for guiding numerous light beams, and FIG. 7B depicts a partial view of the waveguide, shown to an enlarged scale. The light waveguide is columnar-shaped and is approximately 5 μm in diameter.

This value is on the same order of magnitude as the size of the gate of the IGBT or the power MOSFET described above. The light waveguide is secured as it is passed through a socket part of FIG. 7C to constitute an optical circuit. Reports have been made of prototyped products composed of socket rows and matrices of sockets (Non-Patent Document 2).

### FIFTH EXAMPLE

With the use of the light waveguides and the sockets, shown in FIG. 7, light may be guided only to needed portions of the semiconductor apparatus. That is, light may be irradiated to the gate region of the device from the light source through the light waveguide and the socket.

In a well-known manner, an organic EL (electro luminescence) display is a planer light emitting device with a miniaturized structure. It is adjustable in emission intensity of light and may emit light of a variable wavelength. A light emitting element of an LED has a size of 0.1 to 0.3 mm square. Since the size of a semiconductor substrate of the IGBT or the power MOSFET is on the order of 10 mm square, it is necessary to provide for light diffusion means in order to diffuse light over its entire surface.

### SIXTH EXAMPLE

If a planar light emitting device is used as a light source of the ‘optical gate’ structure, the light diffusion means may become unneeded. In this case, switching may be made with light. An IGBT or a power MOSFET, the gate electrode of which is formed of a transparent electrode material, is fabricated, in which an emitter electrode is formed with an opening, as shown for example in FIG. 6. A planar light emitting device is then put on its gate to complete the device. Thereafter, the device is sealed with resin or the like for light shielding. It is noted that the light source for display is relatively lower in frequency response and hence is not suited for high speed switching.

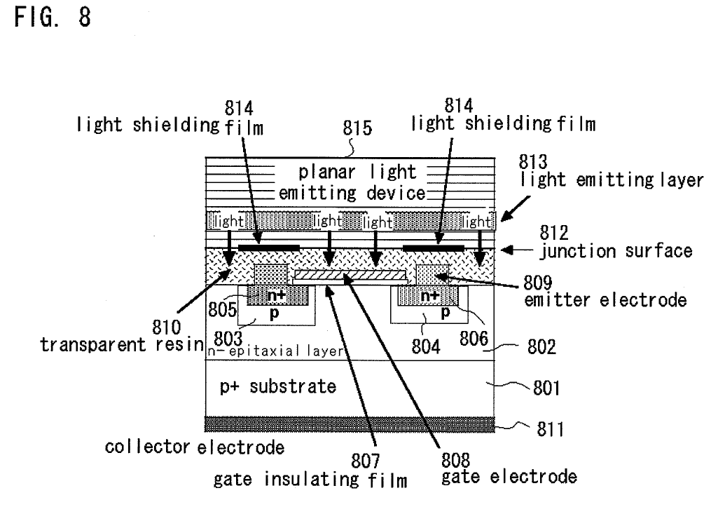

FIG. 8 shows a configuration in which a planar light emitting device (organic EL) 815 is mounted on the IGBT. In this example, light is incident substantially at right angles to the gate of the IGBT. An emitter electrode 809 and a gate electrode 808 are extended in a direction perpendicular to the drawing sheet and are connected at an extreme end, not shown.

An insulating film 810 of, for example, a synthetic resin (transparent resin), is provided in a region of the IGBT below a junction surface 812, and is transmissive to light. If necessary, light shielding members (films) 814 may be provided corresponding to n+ regions 805 and 806, respectively. A planar light emitting device 815 of FIG. 8 is of a thin type.

### SEVENTH EXAMPLE

FIG. 9 schematically shows the cross-section of a seventh example of the present invention. This example includes a point light source, composed of an LED 913, and a light diffusing layer (light diffusing plate) 916. A light reflective plate 915 is arranged on the side of the LED 913 opposite to its side facing the light diffusing plate 916. This light diffusing plate 916 diffuses the light from the LED 913, as point light source, to make the light evenly reach the destination of light illumination, such as gate unit. Light shielding layers 914 may be provided at preset sites of a junction surface 912, as in FIG. 8. The IGBT is connected to a light emitting unit 917 after the deposition of a transparent insulating resin 910 on the IGBT. A switching frequency may be higher because the LED 916 is higher in light emitting efficiency than the organic EL, for instance, and exhibits a high frequency response.

The present example makes use of a point light source and a light diffusing layer. If the point light source is used, an optical fiber may also be used. Alternatively, optical materials may suitably be selected, or the refractive index or transmittance may be controlled to irradiate light in needed portions in a concentrated fashion.

The boundary surface between the transparent gate electrode and the transparent gate insulating film may be lowered in surface roughness to diffuse light. Or, a non-reflective coating may be provided on the boundary surface between the gate electrode and the gate insulating film.

In the examples described above, the light source may include a semiconductor laser.

In the examples described above, said semiconductor laser may be composed of a silicon semiconductor laser.

In the examples described above, said light source may include a silicon semiconductor laser formed on the same silicon wafer on which said switching element is formed.

In the examples described above, said light source may include a silicon semiconductor laser that is formed on the same silicon wafer on which said switching element is formed.

In the examples described above, said silicon semiconductor laser may be arranged next to a gate portion of said switching element and the light emitted from said silicon semiconductor laser is guided to illuminate the gate portion of said switching element from above thereof.

In the examples described above, there is provided a mirror for reflecting said light from said silicon semiconductor laser so as to cause the reflected light to illuminate the gate portion of said switching element from above thereof.

Although the present invention has so far been described with reference to preferred examples, the present invention is not to be restricted to the examples. It is to be appreciated that those skilled in the art can change or modify the examples without departing from the scope and spirit of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor apparatus comprising:
a channel region through which carriers move; and
a light source that irradiates light to a vicinity of the channel region; wherein said light source is turned on to let channel current flow.

2. A semiconductor apparatus comprising:
a switching element; and
a light source that is on/off controlled;
said light source, when turned on, irradiating light to a gate portion of said switching element.

3. The semiconductor apparatus according to claim 2, wherein light irradiation to said gate portion and voltage application to a gate electrode are carried out, when said switching element is on.

4. The semiconductor apparatus according to claim 1, wherein said semiconductor apparatus includes a lateral MOSFET.

5. The semiconductor apparatus according to claim 1, wherein said semiconductor apparatus includes a vertical MOSFET.

6. The semiconductor apparatus according to claim 1, wherein said semiconductor apparatus includes at least one of an IGBT (Insulated Gate Bipolar Transistor), a JFET (Junction gate Field Effect Transistor) and a MESFET (Metal Semiconductor Field Effect Transistor).

7. The semiconductor apparatus according to claim 6, wherein a light reflective plate is provided at the bottom of a trench of a trench gate electrode.

8. The semiconductor apparatus according to claim 2, wherein said gate electrode is an electrically conductive member transmissive to said light; and
a gate insulating film is an insulating member transmissive to said light.

9. The semiconductor apparatus according to claim 2, wherein an insulating resin transmissive to said light is filled in between said gate electrode and said light source.

10. The semiconductor apparatus according to claim 5, wherein said light source is provided in a space between the side of the source electrode of said vertical MOSFET facing the gate electrode thereof and said gate electrode.

11. The semiconductor apparatus according to claim 5, wherein the source electrode of said vertical MOSFET includes an opening having one end facing the gate electrode of said vertical MOSFET and wherein said light source is provided at the opposite end of said opening.

12. The semiconductor apparatus according to claim 10, further including an insulating resin transmissive to said light filled in between said gate electrode and said light source.

13. The semiconductor apparatus according to claim 10, further including a light reflective member, which has been coated or plated, on the surface of said source electrode.

14. The semiconductor apparatus according to claim 6, wherein an emitter electrode of said IGBT is provided with an opening having one end facing a gate electrode of said IGBT and having the other end facing said light source; and
a light reflective plate is provided on an end of said light source opposite to the other end of said opening.

15. The semiconductor apparatus according to claim 1, further including a light waveguide that guides the light from said light source.

16. The semiconductor apparatus according to claim 1, wherein a planar light emitting device, as said light source, is provided facing a surface of said semiconductor apparatus provided with said gate electrode.

17. The semiconductor apparatus according to claim 1, further including:
a light waveguide that guides the light from said light source; and
a light diffusing layer provided in said light waveguide; said light diffusing layer diffusing the light from said light source.

18. The semiconductor apparatus according to claim 1, wherein said light source is provided facing a surface of said semiconductor apparatus on which a gate electrode is provided; said semiconductor apparatus including:
a light diffusing layer provided between said light source and said semiconductor apparatus; and
a light emitting device having a light reflective plate on a side of said light source opposite to the side thereof facing said light diffusing layer.

19. The semiconductor apparatus according to claim 17, further including an insulating resin that covers said gate electrode and is transmissive to the light from said light source.

20. The semiconductor apparatus according to claim 2, including:
a gate electrode composed of an electrically conductive member transmissive to said light;
a gate insulating film composed of an insulating member transmissive to said light; and
a region with relatively low surface roughness provided on a boundary surface between said gate electrode and said gate insulating film to diffuse the light from said light source.

21. The semiconductor apparatus according to claim 20, wherein a non-reflective coating film provided on the boundary surface between said gate electrode and said gate insulating film.

22. The semiconductor apparatus according to claim 1, wherein said light source includes an LED (Light Emitting Diode).

23. The semiconductor apparatus according to claim 10, wherein said light source includes an LED (Light Emitting Diode) and wherein one or more of said LEDs are connected between said source electrode and said gate electrode.

24. The semiconductor apparatus according to claim 16, further including a light shielding member that is provided at a preset site on a junction surface between said semiconductor apparatus and said planar light emitting device.

25. The semiconductor apparatus according to claim 16, wherein said planar light emitting device includes an EL (Electro-Luminescence) device.

26. The semiconductor apparatus according to claim 1, wherein said light source includes a semiconductor laser.

27. The semiconductor apparatus according to claim 26, wherein said semiconductor laser is composed of a silicon semiconductor laser.

28. The semiconductor apparatus according to claim 2, wherein said light source includes a silicon semiconductor laser formed on a silicon wafer on which said switching element is formed.

28. The semiconductor apparatus according to claim 2, wherein said light source includes a silicon semiconductor laser formed on a same silicon wafer on which said switching element is formed.

29. The semiconductor apparatus according to claim 28, wherein said silicon semiconductor laser is arranged next to a gate portion of said switching element and the light emitted from said silicon semiconductor laser is guided to illuminate the gate portion of said switching element from above thereof.

30. The semiconductor apparatus according to claim 29, wherein there is provided a mirror for reflecting said light from said silicon semiconductor laser so as to cause the reflected light to illuminate the gate portion of said switching element from above thereof.
